(19) United States
(12) Patent Application Publication
(10) Pub. No.: US 2007/0102724 A1
(43) Pub. Date: May 10, 2007

(54) Vertical diode doped with antimony to avoid or limit dopant diffusion

(75) Inventors: Tanmay Kumar, Pleasanton, CA (US); S. Brad Herner, San Jose, CA (US)

Correspondence Address: PATENT DEPT., SANDISK 3D LLC(MATRIX), 601 MCCARTHY BOULEVARD, MAILSTOP 116, MILPITAS, CA, 95035, US

(73) Assignee: Matrix Semiconductor, Inc., Santa Clara, CA (US)

(21) Appl. No.: 11/271,078

(22) Filed: Nov. 10, 2005

(51) Int. Cl. H01L 31/111

(52) U.S. Cl. 257/109

(57) ABSTRACT

Use of antimony as an n-type conductivity-enhancing dopant in semiconductor structures having a vertical dopant profile is described. Dopants tend to diffuse, and steep dopant gradients can be difficult to maintain. Specifically, when a silicon layer is doped with phosphorus or arsenic, both n-type dopants, dopant atoms tend to seek the surface as undoped silicon is deposited on top of the n-doped layer, rising through the undoped silicon during deposition. Antimony does not have this tendency, and also diffuses more slowly than either phosphorus or arsenic, and this is advantageously used to dope such structures.

### BACKGROUND OF THE INVENTION

The invention relates to use of antimony as a conductivity-enhancing dopant in semiconductor material.

Semiconductor material such as silicon is frequently doped to enhance conductivity. Such dopants may be either p-type or n-type. A device may have an n-type silicon region adjacent to an undoped silicon region, or adjacent to a p-type silicon region. Maintaining these doping distinctions may be crucial to device performance.

Dopants tend to diffuse, however, particularly when undoped silicon is deposited directly on silicon doped with conventional n-type dopants such as phosphorus or arsenic.

There is a need, therefore, to limit dopant diffusion in semiconductor material, particularly in deposited structures with vertically varying dopant profiles.

### SUMMARY OF THE PREFERRED EMBODIMENTS

The present invention is defined by the following claims, and nothing in this section should be taken as a limitation on those claims. In general, the invention is directed to doping vertical semiconductor structures with antimony.

An aspect of the invention provides for a vertically oriented diode comprising: a first layer of polycrystalline semiconductor material doped with antimony; and a second layer of polycrystalline semiconductor material doped with a p-type dopant, the first layer formed vertically above or below the second layer, wherein the diode is a semiconductor junction diode comprising the first and second layers of polycrystalline semiconductor material.

A preferred embodiment provides for a method to form a nonvolatile memory cell, the method comprising: forming a bottom conductor above a substrate; forming a vertically oriented semiconductor junction diode above the bottom conductor; forming a top conductor above the vertically oriented semiconductor junction diode, wherein a portion of the diode is doped with antimony, and wherein the memory cell comprises a portion of the bottom conductor, the diode, and a portion of the top conductor.

Another preferred embodiment provides for a monolithic three dimensional memory array comprising: a) a first memory level monolithically formed above a substrate, the first memory level comprising: i) a first plurality of substantially parallel, substantially coplanar conductors; ii) a first plurality of vertically oriented semiconductor junction diodes; and iii) a second plurality of substantially parallel, substantially coplanar conductors, the second conductors above the first conductors, wherein each of the first diodes is disposed between one of the first conductors and one of the second conductors, and wherein each of the first diodes comprises a heavily doped n-type region doped with antimony, and b) a second memory level monolithically formed above the first memory level.

A related embodiment provides for a method for forming a monolithic three dimensional memory array, the method comprising: a) monolithically forming a first memory level above a substrate by a method comprising: i) forming a first plurality of substantially parallel, substantially coplanar conductors; ii) forming a first plurality of vertically oriented semiconductor diodes, each first diode comprising a heavily doped n-type region doped with antimony, the first diodes above the first conductors; iii) forming a second plurality of substantially parallel, substantially coplanar conductors, the second conductors above the first diodes; and b) monolithically forming a second memory level above the first memory level.

Each of the aspects and embodiments of the invention described herein can be used alone or in combination with one another.

The preferred aspects and embodiments will now be described with reference to the attached drawings.

### BRIEF DESCRIPTION OF THE DRAWINGS

FIG. 1 is perspective view of a vertically oriented p-i-n diode which may benefit from use of embodiments of the present invention.

FIG. 2 is a perspective view of a nonvolatile memory cell including the vertically oriented diode of FIG. 1.

FIG. 3 is a perspective view of a first memory level of nonvolatile memory cells like those of FIG. 2.

FIG. 4 is a graph showing dopant concentration of phosphorus in an in situ doped silicon stack.

FIGS. 5a-5c are cross-sectional views showing stages in formation of a memory level according to an embodiment of the present invention.

FIG. 6 is a cross-sectional view of a p-n diode which may advantageously be formed according to embodiments of the present invention.

FIGS. 7a and 7b are cross-sectional views of a p-i-n and a p-n diode, respectively, which may advantageously be formed according to embodiments of the present invention.

### DETAILED DESCRIPTION OF THE PREFERRED EMBODIMENTS

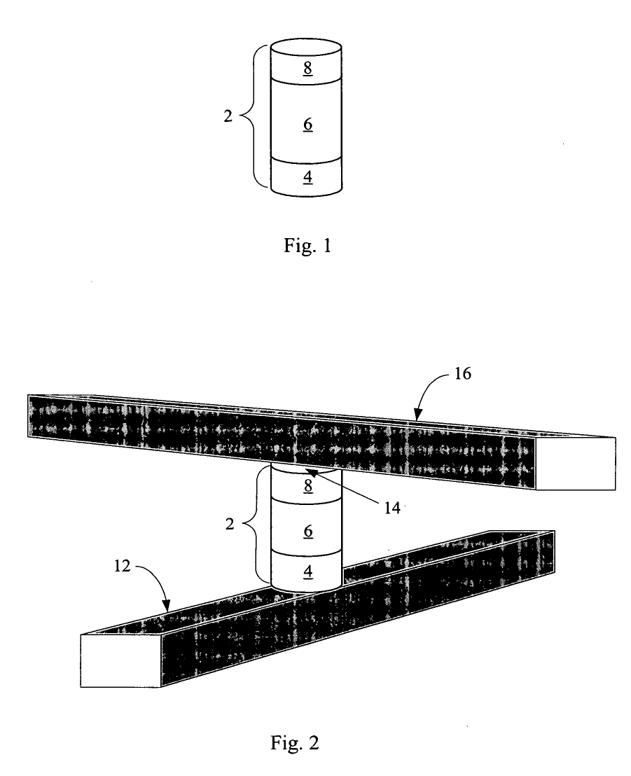

FIG. 1 illustrates a vertically oriented diode 2 formed of deposited semiconductor material, for example silicon. Diode 2 includes a bottom heavily doped region 4, an undoped or intrinsic region 6, and a top heavily doped region 8. Bottom heavily doped region 4 and top heavily doped region 8 are doped with opposite conductivity types: Bottom heavily doped region 4 may be n-type, for example, while top heavily doped region 8 is p-type. Such a diode is used in a nonvolatile memory cell in the monolithic three dimensional memory array described in Herner et al., U.S. Pat. No. 6,952,030, “High-Density Three-Dimensional Memory Cell,” hereinafter the '030 patent; in Herner, U.S. patent application Ser. No. 10/955,549, “Nonvolatile Memory Cell Without a Dielectric Antifuse Having High- and Low-Impedance States,” filed Sep. 29, 2004, hereinafter the '549 application; and in Herner et al., U.S. Pat. application Ser. No. 11/015,824, “Nonvolatile Memory Cell Comprising a Reduced Height Vertical Diode,” filed Dec. 17, 2004, hereinafter the '824 application; all owned by the assignee of the present application and hereby incorporated by reference in their entirety.

Turning to FIG. 2, in the '030 patent, diode 2 is used in a nonvolatile memory cell. Diode 2 is disposed between bottom conductor 12 and top conductor 16, and is separated from top conductor 16 by dielectric rupture antifuse 14. In the '549 application, dielectric rupture antifuse 14 is omitted. In either of the these memory cells, when the cell is initially formed, very low current flows between conductors 12 and 16 when diode 2 is positively biased with a low read voltage. The cell is programmed by applying a large programming current which permanently changes the cell, such that, after programming, when diode 2 is forward biased with a read voltage, a larger, reliably detectable current flows between conductors 12 and 16. The difference in current flow in an unprogrammed and a programmed cell corresponds to a data state of the memory cell, for example “0” or “1”.

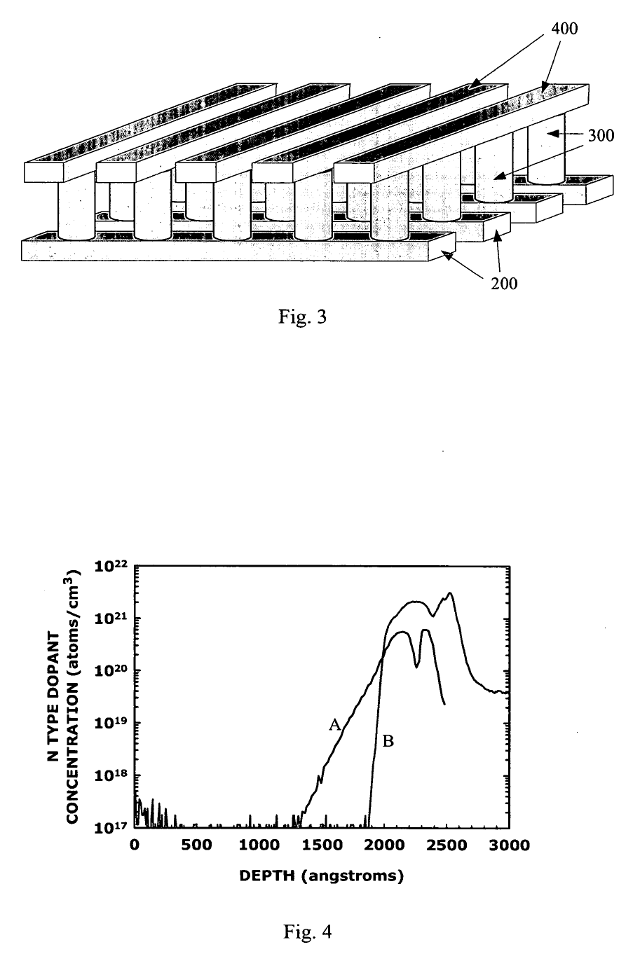

FIG. 3 shows a memory level formed of memory cells like those of FIG. 2, including bottom conductors 200, pillars 300 (each pillar 300 including a diode), and top conductors 400. Multiple memory levels like those of FIG. 3 can be formed stacked above one another, all above a substrate such as a monocrystalline silicon wafer, forming a very dense memory array.

Diode 2 of FIG. 1 can be formed in a variety of ways. Heavily doped regions 4 and 8 can be doped using different methods, including in situ doping or ion implantation. Silicon is typically deposited by flowing a precursor gas which contains silicon, such as SiH_{4,} over a surface in conditions that cause silicon to deposit on the surface. This silicon can be doped in situ, as it is deposited, by simultaneously flowing a donor gas that will provide dopant atoms. For example, if n-type dopant PH₃ is flowed with SiH₄, phosphorus atoms will be deposited along with silicon, doping it. Once the desired thickness of doped silicon has been deposited, forming heavily doped region 4, flow of PH₃ is stopped while SiH₄ flow continues, forming intrinsic region 6.

To dope bottom heavily doped region 4 by ion implantation, silicon region 4 is first deposited undoped. Next ions of the desired dopant are accelerated toward silicon region 4, penetrating it. Once a sufficient doping concentration has been achieved, the surface of heavily doped region 4 is cleaned of contaminants or native oxides (for example by an HF dip) and returned to the deposition chamber, and intrinsic region 6 is deposited on heavily doped region 4.

In practice, however, it may be difficult to maintain the boundary between heavily doped region 4 and intrinsic region 6. A particular challenge arises in structures like those of FIG. 1, in which deposition of silicon continues above a region heavily doped with an n-type dopant. The most commonly used n-type dopants are phosphorus and arsenic. When located in a silicon film, both phosphorus and arsenic tend to seek the surface of that film. Thus when silicon is being deposited with no flow of a donor gas to provide dopant atoms, as during deposition of intrinsic region 6, dopant atoms from heavily doped region 4 tend to migrate upward toward the surface of the silicon. This is true whether heavily doped region 4 was doped by ion implantation or was doped in situ. The concentration of dopant atoms does not stop abruptly when deposition of silicon with no added dopant begins; rather the concentration drops gradually, and a significant thickness of silicon must be deposited without added dopant before dopant concentration drops low enough for the silicon to actually be considered undoped.

FIG. 4, for example, shows concentration of phosphorus in a silicon layer. Depth from the top of the stack increases from left to right across the X-axis; thus the silicon at the right side of the chart was deposited first. The silicon layer was deposited in situ doped with phosphorus until the 2000 angstrom point (note this point is 2000 angstroms deep, measured from the eventual top of the stack once deposition is complete.) At that point, the flow of PH₃ was stopped, and from 2000 angstroms to the surface, no further phosphorus was provided. Nonetheless, as shown on curve A, phosphorus atoms present in the in situ doped thickness migrated upward during subsequent deposition, such that after another 500 angstroms had been deposited (at a depth of 1500 angstroms), the concentration of phosphorus was about 10¹⁸ atoms/cm³, still relatively high.

After deposition is complete, the silicon will generally be amorphous, and will be crystallized by an anneal step, such that the silicon of diode 2 is polycrystalline in the completed device. Elevated temperature during this anneal will also cause dopants to diffuse through the silicon in all directions.

This unwanted dopant diffusion may damage device performance. In the vertically oriented p-i-n diode of FIG. 1, intrinsic region 6 serves to prevent or lessen leakage current when the diode is reverse biased. As the thickness of intrinsic region 6 is decreased due to dopant diffusion from heavily doped region 4 to intrinsic region 6, the leakage current of the diode under reverse bias will increase.

The thickness of intrinsic region 6 can be regained by increasing the overall height of diode 2, but this has disadvantages. As described in the incorporated patents and applications, in preferred embodiments a plurality of diodes like diode 2 is formed by 1) depositing a silicon stack, the bottom region heavily doped as described, 2) patterning and etching the silicon stack to form pillars, 3) depositing dielectric fill between the pillars, 4) planarizing, for example by chemical-mechanical planarization (CMP), to expose the tops of the pillars, and 5) doping tops of the pillars by ion implantation to form the top heavily doped regions, completing the diodes. As the pillars become taller, their aspect ratio, and the aspect ratio of the gaps between them, increases. High-aspect ratio features are difficult to etch and high-aspect ratio gaps are difficult to fill. In addition, as described in the '824 application, reducing the height of the diode reduces the programming voltage required to program the memory cell. Thus it is advantageous to prevent or limit dopant diffusion.

As noted, the most commonly used n-type dopants are phosphorus and arsenic. Another known n-type dopant is antimony. Antimony is much less frequently used, however, as it does not activate as readily as phosphorus or arsenic. (A dopant atom is activated when it donates a charge carrier to the material.)

It has been found that antimony does not exhibit the surface-seeking behavior of phosphorus or arsenic during silicon deposition. Referring to FIG. 4, curve B shows the concentration of antimony in a silicon stack. The first thickness of silicon was deposited, then doped with antimony by ion implantation. Another 2000 angstroms of undoped silicon was deposited on the doped segment. As shown in FIG. 4, the antimony has not migrated into the undoped silicon. Antimony does not diffuse as readily with increased temperature as either phosphorus or arsenic. Thus in the present invention it has been found that antimony can be used advantageously to dope deposited structures in which a vertical dopant profile must be maintained, such as the p-i-n diode of FIG. 1.

A detailed example will be provided describing formation of a monolithic three dimensional memory array in which diodes like those of FIG. 1 are formed according to the present invention. Additional information regarding formation of a similar memory array may be found in the '030 patent, the '549 application, and the '824 application. To avoid obscuring the invention, not all details from this patent and these application will be included, but it will be understood that no teaching of these or any other incorporated patents or applications is intended to be excluded.

For clarity, in this explanation many specific steps and details will be provided; it will be understood by those skilled in the art that this example is for illustration only, is intended to be non-limiting, and that many of the steps and details provided may be altered, augmented, or omitted while the results fall within the scope of the invention.

### EXAMPLE

Fabrication of a single memory level will be described in detail. Additional memory levels can be stacked, each monolithically formed above the one below it.

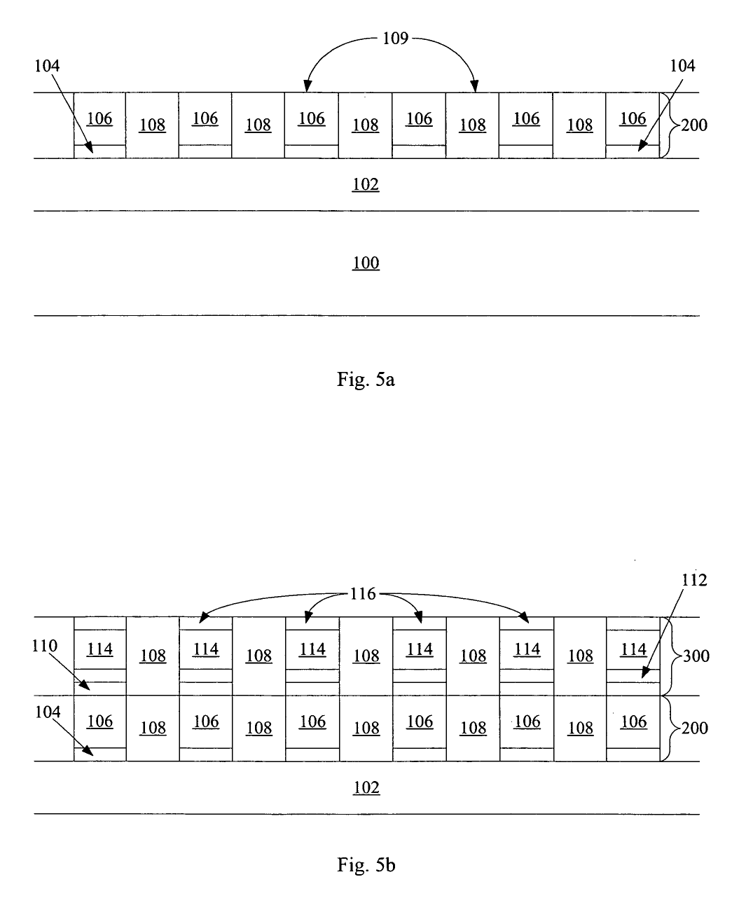

Turning to FIG. 5a, formation of the memory begins with a substrate 100. This substrate 100 can be any semiconducting substrate as known in the art, such as monocrystalline silicon, IV-IV compounds like silicon-germanium or silicon-germanium-carbon, III-V compounds, II-VII compounds, epitaxial layers over such substrates, or any other semiconducting material. The substrate may include integrated circuits fabricated therein.

An insulating layer 102 is formed over substrate 100. The insulating layer 102 can be silicon oxide, silicon nitride, high-dielectric film, Si—C—O—H film, or any other suitable insulating material.

The first conductors 200 are formed over the substrate and insulator. An adhesion layer 104 may be included between the insulating layer 102 and the conducting layer 106 to help the conducting layer 106 adhere. If the overlying conducting layer is tungsten, titanium nitride is preferred as adhesion layer 104.

The next layer to be deposited is conducting layer 106. Conducting layer 106 can comprise any conducting material known in the art, for example tungsten, tungsten nitride, tantalum nitride, etc. Conducting layer 106 must be formed of a material that is thermal compatible with deposition and crystallization of the silicon or silicon alloy diodes that will be formed above it. Bottom conductor 200 is formed above, not in, substrate 100 and in preferred embodiments does not comprise silicon or any other semiconductor material.

Once all the layers that will form the conductor rails 200 have been deposited, the layers will be patterned and etched using any suitable masking and etching process to form substantially parallel, substantially coplanar conductors 200, shown in FIG. 5a in cross-section. In one embodiment, photoresist is deposited, patterned by photolithography and the layers etched, and then the photoresist removed using standard process techniques. Conductors 200 could be formed by a Damascene method instead.

Next a dielectric material 108 is deposited over and between conductor rails 200. Dielectric material 108 can be any known electrically insulating material, such as silicon oxide, silicon nitride, or silicon oxynitride. In preferred embodiments, silicon dioxide is used as dielectric material 108.

Finally, excess dielectric material 108 on top of conductor rails 200 is removed, exposing the tops of conductor rails 200 separated by dielectric material 108, and leaving a substantially planar surface 109. The resulting structure is shown in FIG. 5a. This removal of dielectric overfill to form planar surface 109 can be performed by any process known in the art, such as CMP or etchback. An etchback technique that may advantageously be used is described in Raghuram et al., U.S. application Ser. No. 10/883417, “Nonselective Unpatterned Etchback to Expose Buried Patterned Features,” filed Jun. 30, 2004 and hereby incorporated by reference. At this stage, a plurality of substantially parallel first conductors have been formed at a first height above substrate 100.

Next, turning to FIG. 5b, vertical pillars will be formed above completed conductor rails 200. (To save space substrate 100 is not shown in FIG. 5b; its presence will be assumed.) Preferably a barrier layer 110 is deposited as the first layer after planarization of the conductor rails. Any suitable material can be used in the barrier layer, including tungsten nitride, tantalum nitride, titanium nitride, or combinations of these materials. In a preferred embodiment, titanium nitride is used as the barrier layer. Where the barrier layer is titanium nitride, it can be deposited in the same manner as the adhesion layer 104 described earlier.

Next semiconductor material that will be patterned into pillars is deposited. The semiconductor material is preferably silicon or a silicon-rich alloy. This description will refer to the semiconductor material as silicon, but it will be understood that some other semiconductor material may be used instead.

Bottom heavily doped region 112 will be formed first. Preferably between about 100 and about 500 angstroms of silicon is deposited, most preferably about 200 or about 300 angstroms. After this deposition, the wafer is removed from the chamber and layer 112 is doped with antimony by ion implantation. When used as a conductivity-enhancing dopant, antimony generally does not activate as readily as other n-type dopants, such as phosphorus and arsenic. It may be desirable, then, to dope layer 112 to a somewhat higher dopant concentration than if phosphorus or arsenic were used. For example, dopant concentration may be between about 1×10²⁰ and 5×10²¹ atoms/cm3, preferably between about 1×10²¹ about 2×10²¹ atoms/cm³. The implant energy may be about 25 KeV, for example, while the dose may be between about 5×10¹⁵ and 1×10¹⁶ ions/cm². Next the wafer should be cleaned to remove any oxide that has formed on heavily doped silicon layer 112, for example by an HF dip.

In situ doping of silicon with antimony is not conventional, and equipment to do so is not readily available. If desired, however, heavily doped layer 112 could be in situ doped with antimony during deposition rather than doped by ion implantation. In this detailed example, bottom heavily doped region 112 is n-type, while a top heavily doped region yet to be formed will be p-type. In alternative embodiments, the polarity of the diode could be reversed.

Undoped silicon is deposited next to form intrinsic layer 114. Intrinsic layer 114 can be formed by any method known in the art. The combined thickness of heavily doped layer 112 and intrinsic layer 114 is preferably between about 1400 and about 4300 angstroms, more preferably between about 2000 and about 3800 angstroms.

Referring to FIG. 5b, semiconductor layers 114 and 112, along with underlying barrier layer 110, will be patterned and etched to form pillars 300. Pillars 300 should have about the same pitch and about the same width as conductors 200 below, such that each pillar 300 is formed on top of a conductor 200. Some misalignment can be tolerated.

The pillars 300 can be formed using any suitable masking and etching process. For example, photoresist can be deposited, patterned using standard photolithography techniques, and etched, then the photoresist removed. Alternatively, a hard mask of some other material, for example silicon dioxide, can be formed on top of the semiconductor layer stack, with bottom antireflective coating (BARC) on top, then patterned and etched. Similarly, dielectric antireflective coating (DARC) can be used as a hard mask.

The photolithography techniques described in Chen, U.S. application Ser. No. 10/728436, “Photomask Features with Interior Nonprinting Window Using Alternating Phase Shifting,” filed Dec. 5, 2003; or Chen, U.S. application Ser. No. 10/815312, Photomask Features with Chromeless Nonprinting Phase Shifting Window,” filed Apr. 1, 2004, both owned by the assignee of the present invention and hereby incorporated by reference, can advantageously be used to perform any photolithography step used in formation of a memory array according to the present invention.

Dielectric material 108 is deposited over and between the semiconductor pillars 300, filling the gaps between them. Dielectric material 108 can be any known electrically insulating material, such as silicon oxide, silicon nitride, or silicon oxynitride. In a preferred embodiment, silicon dioxide is used as the insulating material.

Next the dielectric material on top of the pillars 300 is removed, exposing the tops of pillars 300 separated by dielectric material 108, and leaving a substantially planar surface. This removal of dielectric overfill can be performed by any process known in the art, such as CMP or etchback. After CMP or etchback, ion implantation is performed, forming heavily doped p-type top region 116. The p-type dopant is preferably boron or BF₂. In alternative embodiments, heavily doped p-type region 116 could have been doped in situ. The resulting structure is shown in FIG. 5b. After CMP, the combined thickness of regions 112, 114, and 116, the height of the completed diode, is between about 1000 and about 3500 angstroms, preferably less than 3000 angstroms, and in preferred embodiments, less than about 1500 angstroms. In the completed memory array, intrinsic region 114 is preferably at least about 600 angstroms thick, for example at least about 1000 angstroms thick. In the completed memory array (after all thermally induced dopant diffusion has taken place, the dopant concentration in intrinsic region 114 will be less than about 10¹⁸ atoms/cm³, preferably less than 5×10¹⁷ atoms/cm³.

In preferred embodiments, the patterned dimension (width, or dimension in a plane perpendicular to the substrate) of pillars 300 is less than about 150 nm, for example about 130 nm, about 80 nm, or about 65 nm. Pitch is the distance between two adjacent occurrences of a feature in a repeating pattern; the distance from the center of one pillar to the center of the next, for example. In preferred embodiments, then the pitch of pillars 300 (and thus necessarily of conductors 200 as well), is less than about 300 nm, for example about 160 or about 130 nm.

Turning to FIG. 5c, the next element to be formed is optional dielectric rupture antifuse 118. If dielectric rupture antifuse 118 is included, it may be grown by thermal oxidation of a portion of heavily doped p-type region 116. In other embodiments, this layer can be deposited, and may be any appropriate dielectric material. For example, a layer of Al₂O₃ can be deposited at about 150 degrees C. Other materials may be used instead.

Top conductors 400 can be formed in the same manner as bottom conductors 200, for example by depositing adhesion layer 120, preferably of titanium nitride, and conductive layer 122, preferably of tungsten. Conductive layer 122 and adhesion layer 120 are then patterned and etched using any suitable masking and etching technique to form substantially parallel, substantially coplanar conductors 400, shown in FIG. 5c extending left-to-right across the page. Each pillar 300 should be disposed between a bottom conductor 200 and a top conductor 400. Top conductors 400 preferably extend substantially perpendicular to bottom conductors 200. In a preferred embodiment, photoresist is deposited, patterned by photolithography and the layers etched, and then the photoresist removed using standard process techniques.

Next a dielectric material (not shown) is deposited over and between conductor rails 400. The dielectric material can be any known electrically insulating material, such as silicon oxide, silicon nitride, or silicon oxynitride. In a preferred embodiment, silicon oxide is used as this dielectric material.

Formation of a first memory level has been described. Additional memory levels can be formed above this first memory level. In some embodiments, conductors can be shared between memory levels; i.e. top conductor 400 would serve as the bottom conductor of the next memory level. In other embodiments, an interlevel dielectric (not shown) is formed above the first memory level of FIG. 5c, its surface planarized, and construction of a second memory level begins on this planarized interlevel dielectric, with no shared conductors.

The resulting memory array is a monolithic three dimensional memory array. This array comprises a) a first memory level monolithically formed above a substrate, the first memory level comprises: i) a first plurality of substantially parallel, substantially coplanar conductors; ii) a first plurality of vertically oriented semiconductor junction diodes; and iii) a second plurality of substantially parallel, substantially coplanar conductors, the second conductors above the first conductors, wherein each of the first diodes is disposed between one of the first conductors and one of the second conductors, and wherein each of the first diodes comprises a heavily doped n-type region doped with antimony. A second memory level is then monolithically formed above the first memory level.

Circuit layout and biasing schemes advantageously used in a monolithic three dimensional memory array formed according to embodiments of the present invention are described in Scheuerlein, U.S. patent application Ser. No. 10/403,844, “Word Line Arrangement Having Multi-Layer Word Line Segments for Three-Dimensional Memory Array,” filed Mar. 31, 2003, hereby incorporated by reference.

As the germanium content of a silicon-germanium alloy increases, the tendency of phosphorus and arsenic to seek the surface decreases. In general n-type dopants, including antimony, phosphorus, and arsenic, diffuse more readily when exposed to elevated temperatures when germanium content is higher. It's expected, then, that the present invention would used to best advantage in silicon or a silicon-rich alloys, and would provide less benefit as germanium content increases.

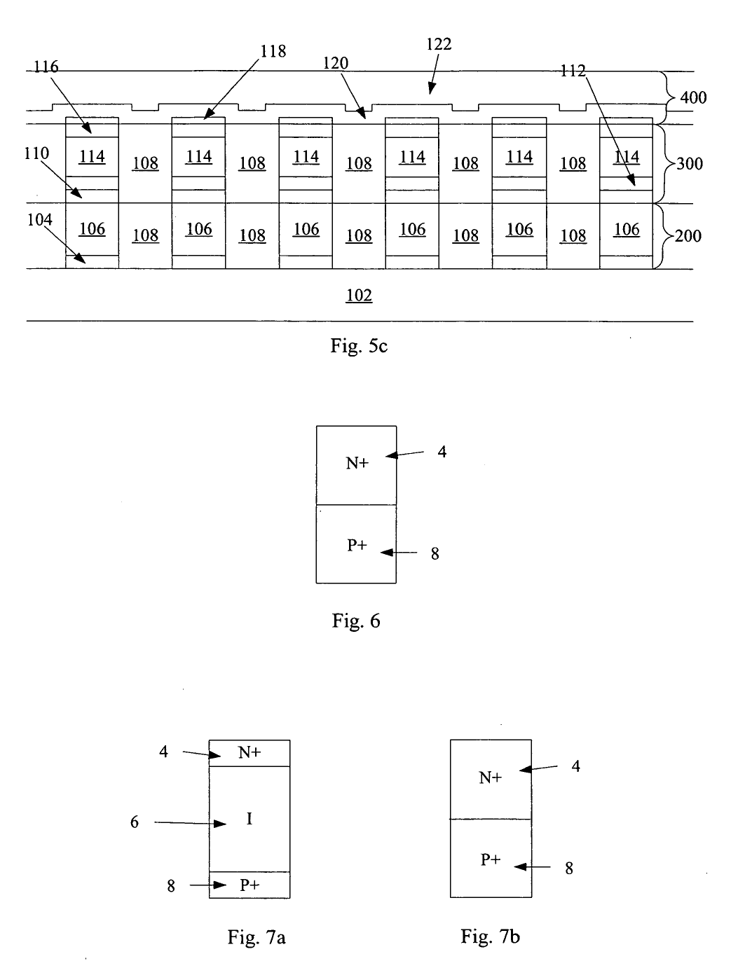

The advantage of using antimony as a dopant for the device of FIG. 1 has been described. The present invention would also provide advantage in other devices formed of semiconductor material having a vertical dopant profile. FIG. 6, for example, shows a p-n diode having little or no intrinsic region between bottom heavily doped n-type region 4 and top heavily doped p-type region 8.

As described, the fact that antimony does not tend to seek the surface during deposition makes its use particularly advantageous when doping an n-type region having an undoped or p-doped region deposited immediately above it. Because of its generally slower rate of diffusion, however, devices such as those shown in FIGS. 7a and 7b, with an n-type region 4 formed above an intrinsic region 6 and heavily doped p-type region 8 (in the p-i-n diode of FIG. 7a); or above heavily doped p-type region 8 (in the p-n diode of FIG. 7b) will also benefit from the use of antimony as a dopant.

The term junction diode is used herein to refer to a semiconductor device with the property of non-ohmic conduction, having two terminal electrodes, and made of semiconducting material which is p-type at one electrode and n-type at the other. Examples include p-n diodes, which have p-type semiconductor material and n-type semiconductor material in contact, such as Zener diodes, and p-i-n diodes, in which intrinsic (undoped) semiconductor material is interposed between p-type semiconductor material and n-type semiconductor material.

Such a vertically oriented diode comprises a first layer of polycrystalline semiconductor material doped with antimony; and a second layer of polycrystalline semiconductor material doped with a p-type dopant, the first layer formed vertically above or below the second layer, wherein the diode is a semiconductor junction diode comprising the first and second layers of polycrystalline semiconductor material. In preferred embodiments, the first layer, doped with antimony, is doped to a concentration of at least 1×10¹⁹ atom/cm³. After programming, the diode is in electrical contact with both a bottom conductor and a top conductor.

A monolithic three dimensional memory array is one in which multiple memory levels are formed above a single substrate, such as a wafer, with no intervening substrates. The layers forming one memory level are deposited or grown directly over the layers of an existing level or levels. In contrast, stacked memories have been constructed by forming memory levels on separate substrates and adhering the memory levels atop each other, as in Leedy, U.S. Pat. No. 5,915,167, “Three dimensional structure memory.” The substrates may be thinned or removed from the memory levels before bonding, but as the memory levels are initially formed over separate substrates, such memories are not true monolithic three dimensional memory arrays.

A monolithic three dimensional memory array formed above a substrate comprises at least a first memory level formed at a first height above the substrate and a second memory level formed at a second height different from the first height. Three, four, eight, or indeed any number of memory levels can be formed above the substrate in such a multilevel array.

The methods of the present invention could be used to advantage in the monolithic three dimensional memory arrays of the '030 patent, the '549 application, the '824 application; and in Herner et al., U.S. patent application Ser. No. 11/125,606, “High-Density Nonvolatile Memory Array Fabricated at Low Temperature Comprising Semiconductor Diodes,” filed May 9, 2005; in Petti et al, U.S. Pat. No. 6,946,719, “Semiconductor Device Including Junction Diode Contacting Contact-Antifuse Unit Comprising Silicide”; and in Herner, U.S. patent application Ser. No. 10/954,510, “Memory Cell Comprising a Semiconductor Junction Diode Crystallized Adjacent to a Silicide,” filed Sep. 29, 2004, all hereby incorporated by reference.

The present invention has been described in the context of a monolithic three dimensional memory array. In such a stacked array, each memory level is subject not only to the thermal stresses of its own fabrication, but also to those necessary to form the memory levels stacked above it. Thus the problems of dopant diffusion are particularly acute in such an array, and the advantages of the present invention particularly advantageous. As will be apparent to those skilled in the art, however, the methods and structures of the present invention are not limited to monolithic three dimensional memory arrays, and can be useful in any deposited semiconductor structure in which use of antimony as a dopant prevents or limits dopant diffusion.

Detailed methods of fabrication have been described herein, but any other methods that form the same structures can be used while the results fall within the scope of the invention.

The foregoing detailed description has described only a few of the many forms that this invention can take. For this reason, this detailed description is intended by way of illustration, and not by way of limitation. It is only the following claims, including all equivalents, which are intended to define the scope of this invention.

What is claimed is:

1. A vertically oriented diode comprising:
a first layer of polycrystalline semiconductor material doped with antimony; and
a second layer of polycrystalline semiconductor material doped with a p-type dopant,
the first layer formed vertically above or below the second layer,
wherein the diode is a semiconductor junction diode comprising the first and second layers of polycrystalline semiconductor material.

2. The diode of claim 1 wherein the polycrystalline semiconductor material of the first layer is silicon or a silicon alloy.

3. The diode of claim 1 wherein the diode is a p-i-n diode or a p-n diode.

4. The diode of claim 3 wherein a layer of intrinsic or lightly doped semiconductor material is between and in contact with the first and second layers.

5. The diode of claim 1 wherein the first layer has a dopant concentration of at least 1×10¹⁹ dopant atoms/cm³.

6. The diode of claim 1 wherein the first layer is doped by in situ doping.

7. The diode of claim 1 wherein the first layer is doped by ion implantation.

8. The diode of claim 1 wherein the diode is disposed above a bottom conductor and below a top conductor and is in electrical contact with the bottom conductor and the top conductor.

9. The diode of claim 8 wherein the bottom conductor does not comprise semiconductor material.

10. The diode of claim 1 wherein the diode has a vertical height less than about 3000 angstroms.

11. The diode of claim 10 wherein the diode has a vertical height less than about 1500 angstroms.

12. The diode of claim 1 wherein the first layer is no more than about 500 angstroms thick.

13. The diode of claim 1 wherein the diode is formed above a monocrystalline silicon substrate.

14. The diode of claim 1 wherein the diode is a portion of a memory cell.

15. The diode of claim 14 wherein the memory cell resides in a monolithic three dimensional memory array.

16. A monolithic three dimensional memory array comprising:
a) a first memory level monolithically formed above a substrate, the first memory level comprising:
i) a first plurality of substantially parallel, substantially coplanar conductors;
ii) a first plurality of vertically oriented semiconductor junction diodes; and
iii) a second plurality of substantially parallel, substantially coplanar conductors, the second conductors above the first conductors,
wherein each of the first diodes is disposed between one of the first conductors and one of the second conductors, and
wherein each of the first diodes comprises a heavily doped n-type region doped with antimony, and
b) a second memory level monolithically formed above the first memory level.

17. The monolithic three dimensional memory array of claim 16 wherein each first diode further comprises a heavily doped p-type region.

18. The monolithic three dimensional memory array of claim 17 wherein each first diode further comprises an intrinsic or lightly doped region between the heavily doped p-type region and the heavily doped n-type region.

19. The monolithic three dimensional memory array of claim 18 wherein the intrinsic or lightly doped region of each first diode is at least 600 angstroms thick.

20. The monolithic three dimensional memory array of claim 19 wherein the intrinsic or lightly doped region of each first diode is at least 1000 angstroms thick.
